(19) United States
(12) Patent Application Publication
(10) Pub. No.: US 2018/0040525 A1
(43) Pub. Date: Feb. 8, 2018

(54) ELECTRONIC COMPONENT-MOUNTED BODY AND METHOD FOR MANUFACTURING SAME

(71) Applicant: FUJIKURA LTD., Tokyo (JP)

(72) Inventor: Hideyuki Wada, Sakura-shi (JP)

(73) Assignee: FUJIKURA LTD., Tokyo (JP)

(21) Appl. No.: 15/667,835

(22) Filed: Aug. 3, 2017

(30) Foreign Application Priority Data
Aug. 8, 2016 (JP) 2016-155713

(51) Int. Cl. H01L 23/14; H01L 23/00; H01L 23/498

(52) U.S. Cl. CPC H01L 23/145; H01L 23/4985; H01L 24/17; H01L 2224/17519; H01L 2224/17505; H01L 2924/3511; H01L 2924/3512

(57) ABSTRACT

An electronic component-mounted body (1) in accordance with an embodiment of the present invention is configured such that an IC chip (20) is fixed, with use of a post (30) having a thermosetting property, to a wiring substrate (10) having an anisotropic linear expansion coefficient.

This nonprovisional application claims priority under 35 U.S.C. §119 on Patent Application No. 2016-155713 filed in Japan on Aug. 8, 2016, the entire contents of which are hereby incorporated by reference.

### TECHNICAL FIELD

The present invention relates to an electronic component-mounted body which includes a wiring substrate and an electronic component mounted on the wiring substrate, and a method for manufacturing the electronic component-mounted body.

### BACKGROUND ART

An electronic component-mounted body (e.g., a printed-circuit-mounted product) which includes a wiring substrate (e.g., a printed wiring board) and an electronic component of various types (e.g., an IC chip) mounted on the wiring substrate is widely employed for use in an electronic device such as a communication device. Patent Literatures 1 through 4 are examples of documents disclosing the electronic component-mounted body.

Patent Literature 1 discloses a microwave/millimeter wave circuit device which is obtained in such a manner that an MMIC (monolithic microwave integrated circuit) chip is mounted on a baseboard by flip chip mounting with use of a bump made of Au or the like, and a gap between the MMIC chip and the baseboard (specifically, an outer side of an insulator wall surrounding the circuit inside the MMIC chip) is filled with underfill.

Patent Literature 2 discloses a semiconductor device which is obtained in such a manner that a semiconductor element is mounted on a circuit board by flip chip mounting with use of both a solder with a low melting point and a solder with a high melting point, and a gap between the semiconductor element and the circuit board is filled with a sealing resin having a flux function.

Patent Literature 3 discloses a wireless device which is obtained in such a manner that a high-frequency IC chip for a power amplifier is mounted on a substrate by flip chip mounting, and a gap between the high-frequency IC chip and the substrate is filled with underfill.

Patent Literature 4 discloses a flip chip mounted structure in which an IC chip is flip-chip mounted on a substrate. The flip chip mounting structure is achieved by providing a post, which is made of a dry film resist, between the IC chip and the substrate in order to hold the IC chip at a predetermined height and fill a space below the IC chip with underfill without letting air bubbles into the underfill.

Flip chip mounting is the fastest method for connecting a circuit of an MMIC chip while allowing the performance of the MMIC chip to be substantially maintained. As such, flip chip mounting is widely used as a method for mounting an MMIC chip to and from which a signal in a microwave band or a millimeter wave band is supplied or outputted.

### CITATION LIST

### Patent Literature

[Patent Literature 1]

Japanese Patent Application Publication Tokukai No. 2000-269384 (Publication date: Sep. 29, 2000)

[Patent Literature 2]

Japanese Patent Application Publication Tokukai No. 2006-54360 (Publication date: Feb. 23, 2006)

[Patent Literature 3]

Japanese Patent Application Publication Tokukai No. 2013-102356 (Publication date: May 23, 2013)

[Patent Literature 4]

Japanese Patent Application Publication Tokukai No. 2001-6805 (Publication date: Mar. 16, 2001)

### SUMMARY OF INVENTION

### Technical Problem

However, none of the conventional techniques above takes into account defective mounting which is caused by a difference between a linear expansion coefficient of a wiring substrate and a linear expansion coefficient of an electronic component mounted on the wiring substrate.

This problem is detailed below, with reference to FIG. 8, on the basis of an example case in which an IC chip (a Si chip) 120 is mounted on an LCP (liquid crystal polymer) substrate 110. The LCP substrate 110 is constituted by an LCP base material 111 and wiring formed on a surface of the LCP base material 111. The LCP base material 111 is a material whose linear expansion coefficient is anisotropic, and has a linear expansion coefficient of 1 ppm/K in an MD (machine direction) direction and a linear expansion coefficient of 64 ppm/K in a TD (transverse direction) direction. Meanwhile, the IC chip 120 has a linear expansion coefficient of approximately 2.6 ppm/K.

FIG. 8 is a view illustrating a method for mounting the IC chip 120 on the LCP substrate 110. (a) through (d) of FIG. 8 are side views each illustrating the IC chip 120 and the LCP substrate 110 in each step of the method. Note that in each of (a) through (d) of FIG. 8, a right-to-left direction of a drawing sheet of FIG. 8 corresponds to the TD direction of the LCP substrate 110.

(a) of FIG. 8 illustrates a state in which the IC chip 120 is mounted on the LCP substrate 110. The LCP substrate 110 includes the LCP base material 111, a substrate wiring layer 112 provided on an upper surface of the LCP base material 111, and a passivation layer 113 provided above the upper surface of the LCP base material 111 so as to cover part of the substrate wiring layer 112. The IC chip 120 includes a semiconductor base material 121, a pad 122 provided on a back surface of the semiconductor base material 121, a Cu pillar 123 connected to the pad 122, and a solder layer 124 provided at a tip of the Cu pillar 123. When the IC chip 120 is mounted on the LCP substrate 110, the tip of the Cu pillar 123 of the IC chip 120 and an exposed portion of the substrate wiring layer 112 of the LCP substrate 110 come in contact with each other via the solder layer 124.

(b) of FIG. 8 illustrates a state in which a reflow process is being performed in a heated atmosphere in order to melt the solder layer 124. In the heated atmosphere, the LCP substrate 110 and the IC chip 120 expand (extend) in the TD direction independently of each other (since the solder layer 124 is melted, the LCP substrate 110 does not accelerate the expansion of the IC chip 120, and the IC chip 120 does not inhibit the expansion of the LC chip 110 either). Since the linear expansion coefficient of the LCP substrate 110 in the TD direction is greater than that of the IC chip 120, an amount of expansion (extension) of the LCP substrate 110 in the TD direction is greater than that of the IC chip 120.

(c) of FIG. 8 illustrates a state in which the atmosphere is cooled down (has returned to room temperature) after completion of the reflow process. In accordance with the cooling of the atmosphere, the IC chip 120 contracts toward a central part (indicated by a broken line in (c) of FIG. 8) of the IC chip 120. Meanwhile, the LCP base material 111 remains in an expanded state due to having thermoplasticity. This either causes the solder layer 124 to break so that the Cu pillar 123 falls off from the exposed portion of the substrate wiring layer 112, or causes the LCP substrate 110 to be warped as illustrated in (c) of FIG. 8.

In a case where an external force is applied to the LCP substrate 110 in a direction indicated by an arrow in (d) of FIG. 8 in order to cancel the warpage of the LCP substrate 110, the solder layer 124 is broken by stress applied in a shear direction, so that the Cu pillar 123 becomes detached from the exposed portion of the substrate wiring layer 112, as illustrated in a part surrounded by a broken line in (e) of FIG. 8.

It is thus possible that expansion of an IC chip and an LCP substrate at respective different linear expansion coefficients in a heating (reflow) step during solder connection causes a defective solder connection.

Note that FIG. 8 is concerned with the TD direction, in which the linear expansion coefficient of the LCP substrate 110 is 64 ppm/K. In the example illustrated in FIG. 8, there is no significant difference in linear expansion coefficient between the LCP substrate 110 and the IC chip 120 in the MD direction, in which the linear expansion coefficient of the LCP substrate 110 is 1 ppm/K. Accordingly, the above-described defect in the TD direction is not caused in the MD direction.

The present invention is accomplished in view of the foregoing problem. An object of the present invention is to provide: an electronic component-mounted body which includes a wiring substrate and an electronic component mounted on the wiring substrate and enables prevention of defective mounting which is caused by a difference in linear expansion coefficient between the wiring substrate and the electronic component; and a method for manufacturing the electronic component-mounted body.

### Solution to Problem

In order to attain the object, an electronic component-mounted body in accordance with the present invention is an electronic component-mounted body including: a wiring substrate; and an electronic component including a terminal connected to wiring of the wiring substrate by soldering, the electronic component being fixed to the wiring substrate with use of a post which is made of a thermosetting resin and not in contact with the wiring and the terminal.

Further, in order to attain the object, a method, in accordance with the present invention, for manufacturing an electronic component-mounted body is a method for manufacturing an electronic component-mounted body including a wiring substrate and an electronic component, the method including: a deposition step of causing a thermosetting resin in an uncured state to be deposited (i) on the wiring substrate into a columnar shape without bringing the thermosetting resin into contact with wiring of the wiring substrate or (ii) on the electronic component into a columnar shape without bringing the thermosetting resin into contact with a terminal of the electronic component; a contact step of bringing the terminal of the electronic component into contact with the wiring via solder without bringing the thermosetting resin into contact with the terminal and the wiring; a heating step of heating the thermosetting resin and the solder so as to cure the thermosetting resin and also to melt the solder; and a cooling step of cooling the solder so as to cure the solder.

### Advantageous Effects of Invention

According to an embodiment of the present invention, it is possible to provide an electronic component-mounted body which enables prevention of defective mounting which is caused by a difference in linear expansion coefficient between a wiring substrate and an electronic component mounted on the wiring substrate.

### BRIEF DESCRIPTION OF DRAWINGS

FIG. 1 is a view illustrating a configuration of an embodiment of an electronic component-mounted body in accordance with the present invention. (a) of FIG. 1 is a top view of the electronic component-mounted body, (b) of FIG. 1 is a cross-sectional view taken along a line A-A′ in (a) of FIG. 1, and (c) of FIG. 1 is a cross-sectional view taken along a line B-B′ in (a) of FIG. 1.

FIG. 2 is a flowchart showing a method for manufacturing the electronic component-mounted body illustrated in FIG. 1.

FIG. 3 is a cross-sectional view illustrating a process for manufacturing the electronic component-mounted body manufactured in accordance with the flowchart of FIG. 2.

FIG. 4 is a view illustrating a configuration of another embodiment of the electronic component-mounted body in accordance with the present invention. (a) of FIG. 4 is a top view of the electronic component-mounted body, (b) of FIG. 4 is a cross-sectional view taken along a line A-A′ in (a) of FIG. 4, and (c) of FIG. 4 is a cross-sectional view taken along a line B-B′ in (a) of FIG. 4.

FIG. 5 is a top view illustrating a configuration of still another embodiment of the electronic component-mounted body in accordance with the present invention.

FIG. 6 is a top view illustrating a configuration of still another embodiment of the electronic component-mounted body in accordance with the present invention.

FIG. 7 is a cross-sectional view illustrating a configuration of still another embodiment of the electronic component-mounted body in accordance with the present invention.

FIG. 8 is a view illustrating a conventional configuration.

### DESCRIPTION OF EMBODIMENTS

### Embodiment 1

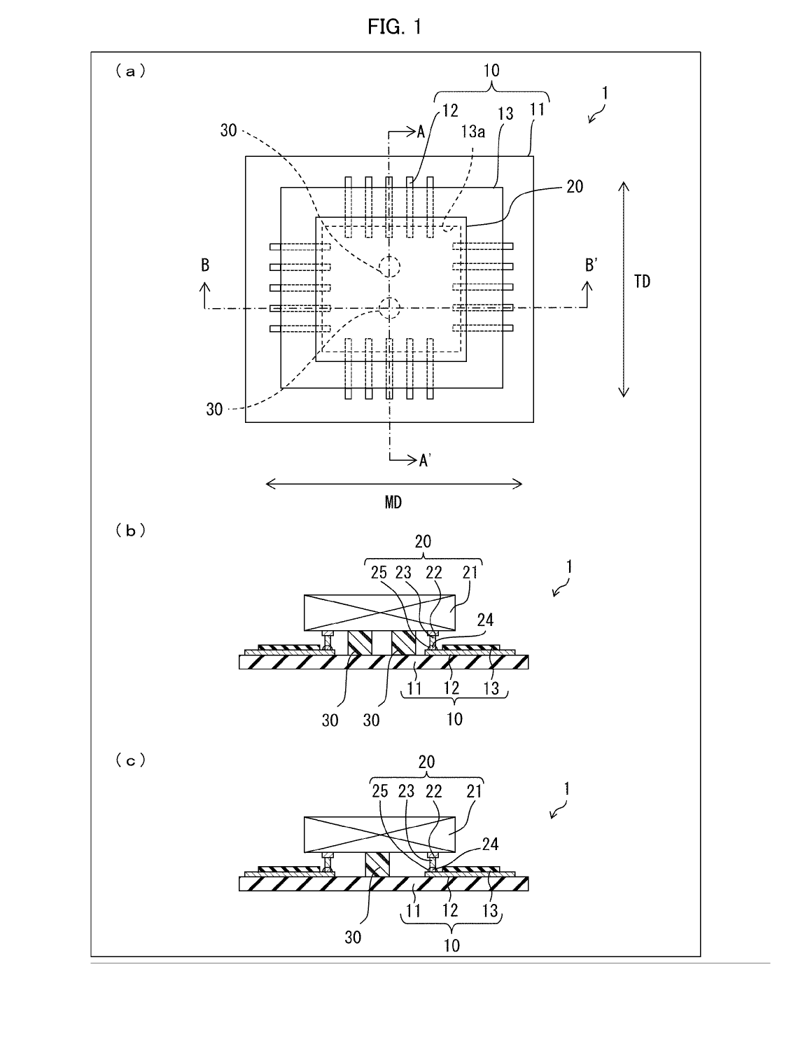

The following description will discuss, with reference to FIGS. 1 through 3, an embodiment of an electronic component-mounted body in accordance with the present invention and a method for manufacturing the electronic component-mounted body.

[Configuration of Electronic Component-Mounted Body]

FIG. 1 is a view schematically illustrating a configuration of an electronic component-mounted body 1 in accordance with Embodiment 1. (a) of FIG. 1 is a top view of the electronic component-mounted body 1, (b) of FIG. 1 is a cross-sectional view taken along a line A-A′ in (a) of FIG. 1, and (c) of FIG. 1 is a cross-sectional view taken along a line B-B′ in (a) of FIG. 1. Note that for easy explanation, (a) of FIG. 1 partially includes a transparent view.

The electronic component-mounted body 1 in accordance with Embodiment 1 includes a wiring substrate 10, an IC chip 20 (electronic component), and posts 30.

The wiring substrate 10 includes an LCP base material 11, a substrate wiring layer 12 (wiring) provided on an upper surface of the LCP base material 11, and a passivation layer 13 provided over the upper surface of the LCP base material 11 so as to cover part of the substrate wiring layer 12. As illustrated in (a) of FIG. 1, the LCP base material 11 has the upper surface which has a quadrangular shape and on which a plurality of wires constituted by the substrate wiring layer 12 are provided so as to extend from a peripheral edge portion of the LCP base material 11 to a central part of the upper surface of the LCP base material 11. Note that the number of the plurality of wires constituted by the substrate wiring layer 12 is not limited to the number illustrated in (a) of FIG. 1. The passivation layer 13 is provided so as to cover a middle portion of each of the plurality of wires, and has an opening 13a in a central part of the passivation layer 13. Due to the provision of the passivation layer 13 in this fashion, both ends of each of the plurality of wires are exposed so as to constitute a connection terminal.

To describe the LCP base material 11 in further detail, a linear expansion coefficient of the LCP base material 11 is anisotropic on the upper surface of the LCP base material 11. Specifically, a linear expansion coefficient of the LCP base material 11 in a TD direction (first direction) shown in (a) of FIG. 1 is greater than that in a MD direction (second direction). For example, the LCP base material 11 has a linear expansion coefficient of 64 ppm/K in the TD direction shown in (a) of FIG. 1 and a linear expansion coefficient of 1 ppm/K in the MD direction shown in (a) of FIG. 1. That is, the LCP base material 11 has a property of extending, when heated, along the TD direction to a greater extent than along the MD direction. Note that in Embodiment 1, the LCP base material 11 is film-shaped and flexible. Even in a state where the substrate wiring layer 12 and the passivation layer 13 are provided on the LCP base material 11 (i.e., in a state where the wiring substrate 10 is formed), the LCP base material 11 maintains the flexibility and the above-described anisotropy of the LCP base material 11.

As illustrated in (a) of FIG. 1, the IC chip 20 has a semiconductor base material 21 having a quadrangular-shaped upper surface. Further, as illustrated in (b) of FIG. 1, the IC chip 20 has (i) a Cu pillar 23 provided on an I/O pad 22 on a back surface of the semiconductor base material 21, the I/O pad 22 being an (external) terminal of an MMIC, and (ii) a solder layer 24 and a flux agent 25 which are provided at a tip of the Cu pillar 23. A plurality of the I/O pads 22 are provided in a peripheral edge portion of the quadrangular-shaped back surface of the semiconductor base material 21 (for example, in a peripheral arrangement) so as to each be located in a position facing the connection terminal of the substrate wiring layer 12, which connection terminal is exposed in a central part of the wiring substrate 10.

Note that a region of the back surface of the IC chip 20 (the semiconductor base material 21) in which region the I/O pad 22 is provided is hereinafter referred to as a “terminal-provided region,” and a region of the back surface in which region no I/O pad 22 is provided is hereinafter referred to as a “terminal-less region.” That is, in Embodiment 1, a peripheral part of the back surface of the IC chip 20 (the semiconductor base material 21) which peripheral part extends along four edges of the back surface is the terminal-provided region, and a region which is surrounded by the peripheral part and includes a central part of the back surface is the terminal-less region.

Note that an integrated circuit (IC) of the IC chip 20 may be a well-known high-frequency IC other than the MMIC, or may be even any well-known IC without being restricted to a high-frequency one.

The posts 30 are each a columnar structure which stands upright between the terminal-less region of the IC chip 20 and the upper surface of the LCP base material 11 (the wiring substrate 10) so as to be in contact with the terminal-less region and a region of the upper surface of the LCP base material 11 which region faces the terminal-less region. More specifically, (i) a lower end of each post 30 is fixedly in contact with the central part and the vicinity thereof of the upper surface of the LCP base material 11, the central part and the vicinity thereof not being provided with the substrate wiring layer 12, and (ii) an upper end of the post 30 is fixedly in contact with the terminal-less region of the IC chip 20. Since a high-frequency signal is transmitted through a terminal of the IC chip 20, specific inductive capacity/dielectric dissipation factor of an insulating resin applied around the terminal has a significant influence on transmission loss. Accordingly, the atmosphere, which has a specific inductive capacity of approximately 1, is desirable. In view of this, the posts 30 are preferably provided in a central part (i.e., terminal-less region) of the IC chip 20, so that the mounted body has an improved strength and the transmission characteristics of the IC terminal is prevented from degrading.

The posts 30 are made of a resin which has a thermosetting property and an insulating property and also exhibits a good adhesion property between the LCP base material 11 and the IC chip 20. Specifically, an insulating resin containing epoxy as a main component and cures at a curing temperature of 200° C. to 250° C. within 10 seconds is used. Note that the resin constituting the posts 30 does not have to have an insulating property, but in a case where the resin may affect the electrical characteristics of the IC chip 20, it is preferable that the resin be an insulating resin. As described later, the resin constituting the posts 30 has a high thixotropy, and preferably has a viscosity of 45,000 Pa·s to 300,000 Pa·s before being heated (before being thermally cured). Further, the thermosetting resin constituting the posts 30 preferably contracts as being thermally cured.

The provision of the posts 30 having as described above allows a position of the LCP base material 11 (the wiring substrate 10) to be fixed at a contact portion between the LCP base material 11 (the wiring substrate 10) and the lower end of each of the posts 30 at a heating step of a reflow process during mounting. This suppresses expansion of the LCP base material 11 (the wiring substrate 10) at the contact portion and a region around the contact region. Note here that the IC chip 20 has a linear expansion coefficient of approximately 2.6 ppm/K. As such, fixation of the position of the LCP base material 11 by the posts 30 with respect to the TD direction, in which the linear expansion coefficient of the LCP base material 11 is 64 ppm/K, allows suppressing expansion of the LCP base material 11 in the TD direction. With respect to the MD direction, in which the LCP base material 11 has a linear expansion coefficient of 1 ppm/K, the IC chip 20 expands to a slightly greater extent than the LCP base material 11. However, since a difference in linear expansion coefficient between the IC chip 20 and the LCP base material 11 is only minor, defective mounting due to a difference in amount of expansion is unlikely to occur.

Further, in Embodiment 1, two posts 30 (a post and another post) are arranged along the TD direction as illustrated in (a) of FIG. 1. As described above, a linear expansion coefficient of the LCP base material 11 in the MD direction is greater than that in the TD direction. As such, the provision of the posts 30 at a plurality of positions on the same line along the TD direction allows efficiently suppressing, with use of a limited number of posts 30, expansion along the TD direction which is caused by heat.

Note here that a sum of (i) a length of one of the posts 30 along the TD direction (more precisely, the same line described above) in a contact region between the one of the posts 30 and the LCP base material 11 and (ii) a length of the other of the posts 30 along the TD direction (more precisely, the same line described above) in a contact region between the one other of the posts 30 and the LCP base material 11 is defined as X. X is a sum of the widths of the respective posts 30 as measured along a right-to-left direction of a drawing sheet of (b) of FIG. 1. Meanwhile, a length of each post 30 in a contact region between the post 30 and the LCP base material 11 as measured along another direction is defined as Y. Y, for example, is a width of each post 30 as measured along a right-to-left direction of a drawing sheet of (c) of FIG. 1. X and Y are in a relation of X>Y.

Designing the posts 30 as described above allows the position of the LCP base material 11 to be fixed across a relatively large width along the TD direction. This enables effective suppression of expansion of the LCP base material 11 in the TD direction.

Thus, according to Embodiment 1, it is possible to provide an electronic component-mounted body which, due to including the posts 30, enables suppression of expansion of the LCP base material 11 in the TD direction and, accordingly, enables prevention of defective mounting caused by a difference in linear expansion coefficient between the LCP base material 11 and the IC chip 20.

Note that a gap between the IC chip 20 and the LCP base material 11 of the electronic component-mounted body 1 in accordance with Embodiment 1 is not sealed by an underfill material. That is, the electronic component-mounted body 1 has an empty space (air layer) under the IC chip 20.

Note that, as illustrated in (a) of FIG. 1, each of the posts 30 is a columnar structure having a circular shape when viewed from above, but the shape of each of the posts 30 when viewed from above is not limited to this.

[Method for Manufacturing Electronic Component-Mounted Body]

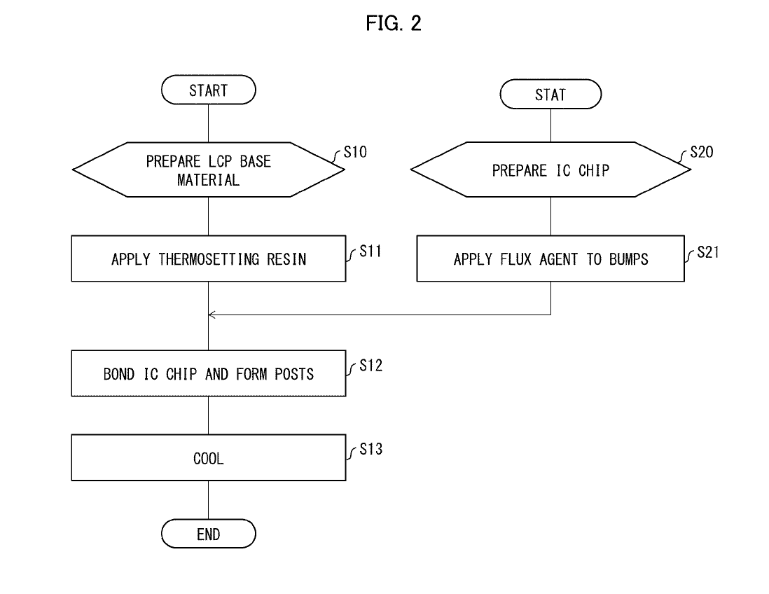

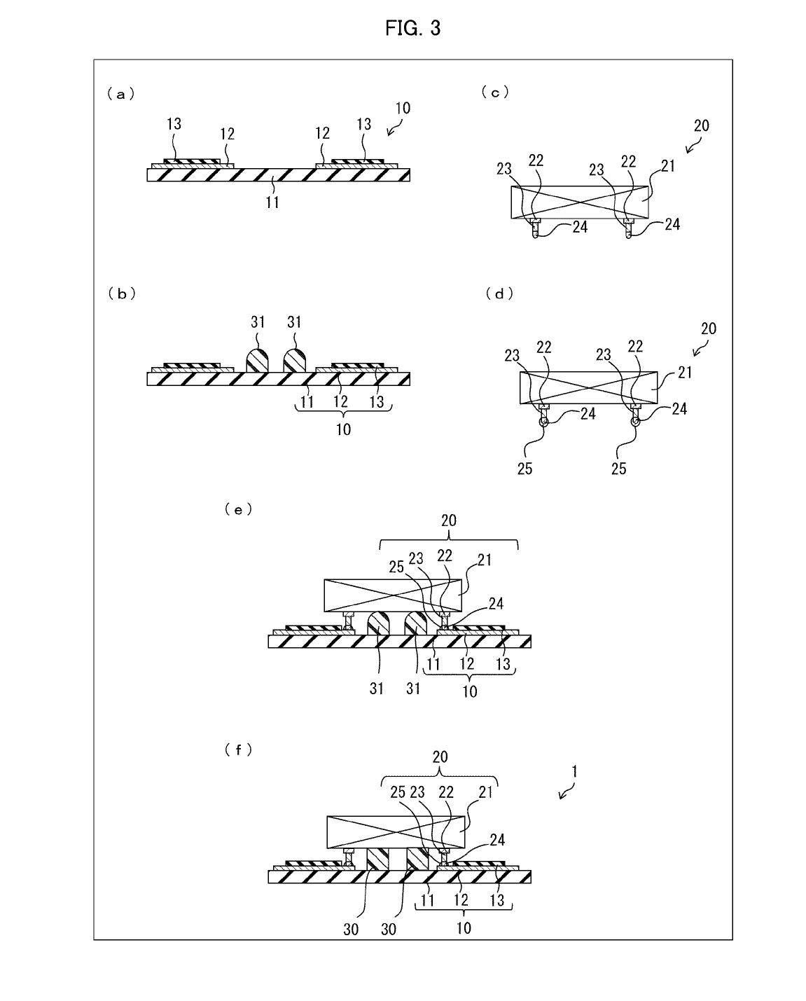

The following description will discuss, with reference to FIGS. 2 and 3, a method for manufacturing the electronic component-mounted body 1 which has the configuration as described above. FIG. 2 is a flowchart for explaining a method for manufacturing the electronic component-mounted body 1. FIG. 3 is a view illustrating a method for manufacturing the electronic component-mounted body 1. (a) through (f) of FIG. 3 are each a cross-sectional view of the wiring substrate 10 (the LCP base material 11) and the like viewed from the same direction as in (b) of FIG. 1.

First, the wiring substrate 10 is prepared (FIG. 2: step S10). Specifically, on the upper surface of the LCP base material 11, the substrate wiring layer 12 (e.g., Cu/Ni/Au), which constitutes (i) a wiring part, (ii) a reception pad for receiving the IC chip, and (iii) an I/O pad to be connected with wiring, another substrate, and the like, is formed by a method such as plating. Further, the passivation layer 13 is formed on the upper surface of the LCP base material 11 so as to cover the wiring part, which is not externally connected, of the substrate wiring layer 12. This state is illustrated in (a) of FIG. 3.

Subsequently, on the upper surface of the LCP base material 11 (the wiring substrate 10), a resin from which the posts 30 are to be made and which is in an uncured state prior to heating is applied to the central part and the vicinity thereof, which are not provided with the substrate wiring layer 12, so that the resin is deposited so as to form post precursors 31 each having a columnar shape (FIG. 2: step S11, deposition step). Since the resin to be applied has a high thixotropy, application of the resin to the same position continuously or intermittently causes the resin to be deposited in a direction perpendicular to the upper surface while spread of the resin along the upper surface is suppressed. Thus, the columnar post precursors 31 are obtained. This state is illustrated in (b) of FIG. 3. Note that a method for applying the resin may be application with use of a dispenser, or application by an inkjet method or printing.

As for the IC chip 20, the IC chip 20 illustrated in (c) of FIG. 3, which includes (i) the MMIC (not illustrated) provided on the back surface of the semiconductor base material 21, (ii) the I/O pad 22, (iii) the Cu pillar 23 provided on the I/O pads 22 and having a height of, for example, 25 μm to 50 μm, and (iv) the solder layer 24 (e.g., SnAg solder) provided at the tip of the Cu pillar 23, is prepared (FIG. 2: step S20).

Subsequently, flux is applied onto the solder layer 24 of the IC chip 20 so as to form the flux agent 25 (FIG. 2: step S21). This state is illustrated in (d) of FIG. 3.

Then, to the upper surface of the wiring substrate 10, on which the columnar post precursor 31 has been formed through the step S11 of FIG. 2, the IC chip 20 formed through the step S21 of FIG. 2 is bonded (contact step). At this time, the tips of the columnar post precursors 31 come in contact with the terminal-less region of the IC chip 20. This state is illustrated in (e) of FIG. 3.

Subsequently, reflow is carried out in a heated atmosphere (FIG. 2: step S12, heating step). In the heated atmosphere, the columnar post precursor 31 is gradually cured by heat so as to become the posts 30, and also the solder layer 24 and the flux agent 25 of the IC chip 20 melt so as to be electrically connected to the reception pad of the substrate wiring layer 12 of the wiring substrate 10. Note that the reflow may be carried out by heating through a stage on which the wiring substrate 10 is placed or heating through a tool holding the IC chip 20 and the like.

Then, at a step S13 shown in FIG. 2, the heating is ended and cooling is performed (back to normal temperature) (cooling step). This causes the solder layer 24 and the flux agent 25 of the IC chip 20 to be cured while the solder layer 24 and the flux agent 25 are in contact with the reception pad of the substrate wiring layer 12 of the wiring substrate 10. Thus, connection between the IC chip 20 and the substrate wiring layer 12 by soldering is completed. This state is illustrated in (f) of FIG. 3.

Through the flow described above, the electronic component-mounted body 1 in accordance with Embodiment 1 is completed.

### Modified Example 1

Embodiment 1 described above has provided an example case in which the LCP base material 11 having a film-shaped is used, but the present invention is not limited to this. It is possible to employ a rigid substrate. Further, it is also possible to employ a substrate (base material) other than a liquid crystal polymer which substrate (base material) has an anisotropic linear expansion coefficient. Examples of a rigid substrate having an anisotropic linear expansion coefficient encompass a ceramic substrate, which is usable in the present invention. Further, it is possible to employ a substrate which is made of a material whose linear expansion coefficient is not anisotropic.

Note here that even in a case where the IC chip (electronic component) has a linear expansion coefficient which exceeds the wiring substrate to a relatively significant extent, the posts in accordance with an aspect of the present invention are cured at the time of melting of the solder and thus suppress expansion of the IC chip. As described above, the IC chip contracts after an end of reflow so as to return to or approximate to a state before the reflow. As such, in a case where expansion of the IC chip is suppressed by the posts, the IC chip contracts less after the end of the reflow as compared with a case in which the expansion is not suppressed by the posts. It is thus possible to reduce warpage of the wiring substrate caused by a contraction of the electronic component.

### Modified Example 2

Although two posts 30 are distanced from each other in Embodiment 1 described above, the present invention is not limited to this and can employ a configuration in which two posts 30 are in contact with each other.

Furthermore, the number of positions at which the posts 30 are provided is not limited to two, but can be three or more.

### Modified Example 3

In Embodiment 1 described above, formation of the post precursors 31 in the production flow shown in FIG. 2 is performed in such a manner that a resin from which the posts 30 are to be made and which is in an uncured state is applied to the central part and the vicinity thereof, which are not provided with the substrate wiring layer 12, of the upper surface of the LCP base material 11 (the wiring substrate 10). However, the present invention is not limited to this. It is possible to form post precursors by applying, to the terminal-less region of the IC chip 20, a resin from which the posts 30 are to be made and which is in an uncured state.

### Embodiment 2

The electronic component-mounted body in accordance with the present invention is not limited to the configuration illustrated in FIG. 1 of the electronic component-mounted body 1 in accordance with Embodiment 1. For example, while the electronic component-mounted body 1 illustrated in FIG. 1 has a configuration in which two posts 30 are arranged along the TD direction, it is possible to employ an alternative aspect described below.

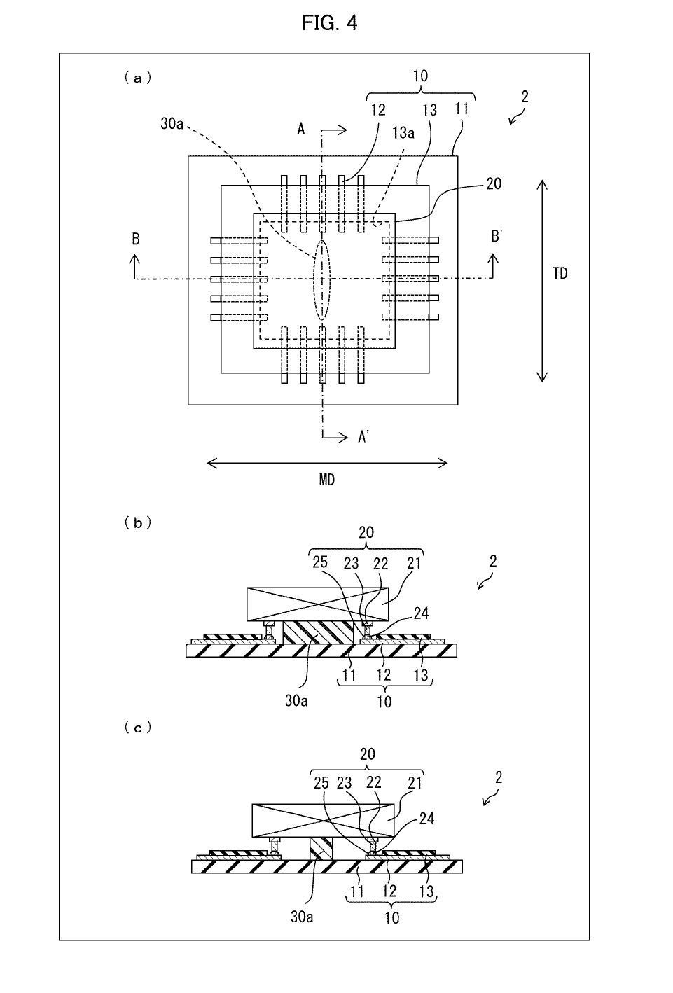

FIG. 4 is a view schematically illustrating a configuration of an electronic component-mounted body 2 in accordance with Embodiment 2. (a) of FIG. 4 is a top view of the electronic component-mounted body 2, (b) of FIG. 4 is a cross-sectional view taken along a line A-A′ in (a) of FIG. 4, and (c) of FIG. 4 is a cross-sectional view taken along a line B-B′ in (a) of FIG. 4. For easy explanation, (a) of FIG. 4 partially includes a transparent view. Further, for easy explanation, the same reference signs will be given to members having the same function as a member described in Embodiment 1, and descriptions on such a member will be omitted.

As illustrated in FIG. 4, in Embodiment 2, a single post 30a is provided in place of the two posts 30 in accordance with Embodiment 1.

Similarly to the posts 30 in accordance with Embodiment 1, the post 30a is a columnar structure which stands upright between a terminal-less region of an IC chip 20 and an upper surface of a wiring substrate 10 so as to be in contact, at a single position, with the terminal-less region and in contact, at a single position, with a region of the upper surface of the wiring substrate 10 which region faces the terminal-less region. However, the post 30a in accordance with Embodiment 2 differs from the two posts 30 in accordance with Embodiment 1 in being a single post 30a which has a shape of an ellipse having a long axis parallel to a TD direction of the wiring substrate 10 (an LCP base material 11) and a short axis parallel to an MD direction of the wiring substrate 10 (the LCP base material 11).

That is, between the IC chip 20 and the wiring substrate 10 (the LCP base material 11), the post 30a is in contact with the IC chip 20 and the LCP base material 11 across a wide width along the TD direction (a right-to-left direction of a drawing sheet of (b) of FIG. 4) as illustrated in (b) of FIG. 4 and in contact with the IC chip 20 and the LCP base material 11 across a small width along the MD direction (a right-to-left direction of a drawing sheet of (c) of FIG. 4) as illustrated in (c) of FIG. 4.

Note that the post 30a is made of the same resin as that of the posts 30 in accordance with Embodiment 1.

Thus, a length of the post 30a in a contact region between the post 30a and the wiring substrate 10 (the LCP base material 11) is longer in a direction in which the LCP base material 11 has a greater linear expansion coefficient. This allows expansion of the wiring substrate 10 in the TD direction to be suppressed in a similar manner to Embodiment 1.

### Embodiment 3

The electronic component-mounted body in accordance with the present invention is not limited to the configuration illustrated in FIG. 1 of the electronic component-mounted body 1 in accordance with Embodiment 1. For example, while the electronic component-mounted body 1 illustrated in FIG. 1 has a configuration in which two posts 30 are arranged along the TD direction, it is possible to employ an alternative aspect described below.

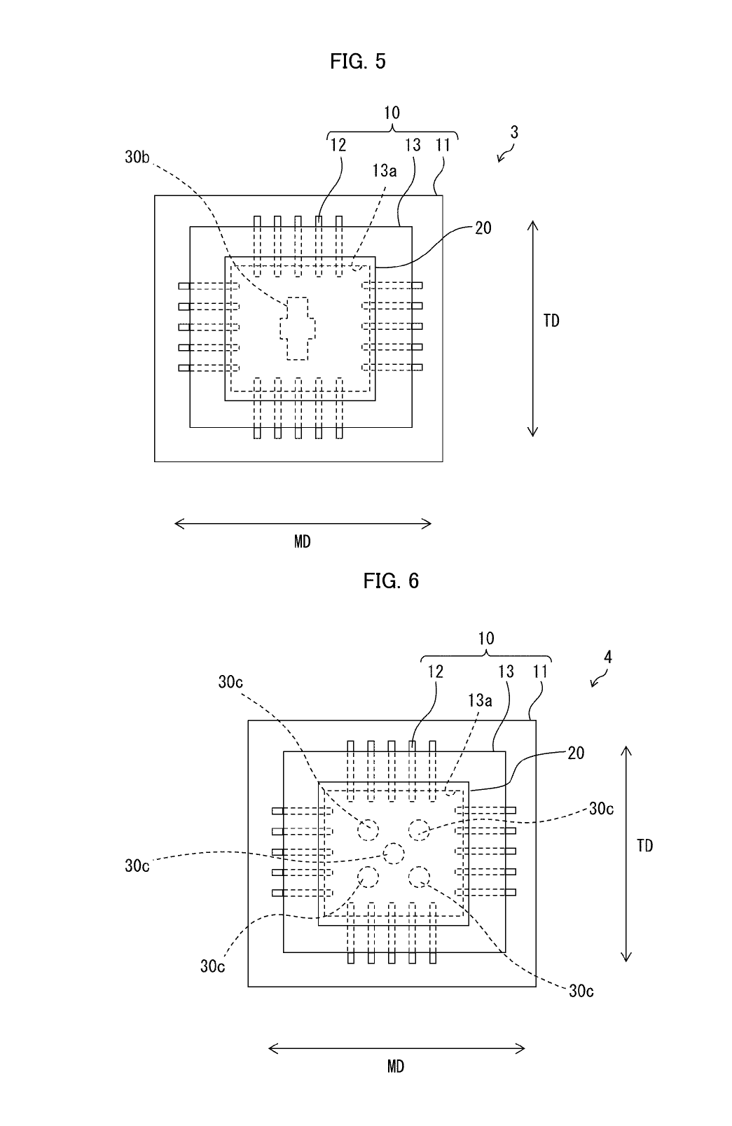

FIG. 5 is a top view schematically illustrating a configuration of an electronic component-mounted body 3 of Embodiment 3. For easy explanation, FIG. 5 partially includes a transparent view. Further, for easy explanation, the same reference signs will be given to members having the same function as a member described in Embodiment 1, and descriptions on such a member will be omitted.

As illustrated in FIG. 5, in Embodiment 3, a single post 30b is provided in place of the two posts 30 in accordance with Embodiment 1.

Similarly to the posts 30 in accordance with Embodiment 1, the post 30b is a columnar structure which stands upright between a terminal-less region of an IC chip 20 and an upper surface of a wiring substrate 10 so as to be in contact with the terminal-less region and a region of the upper surface of the wiring substrate 10 which region faces the terminal-less region. However, the post 30b in accordance with Embodiment 3 differs from the two posts 30 in accordance with Embodiment 1 in having a shape of a cross when viewed from above.

More specifically, a contact surface of the post 30b in accordance with Embodiment 3, which contact surface is in contact with the upper surface of the wiring substrate 10, has a shape of a cross that is a combination of (i) a first rectangle having a long side parallel to a TD direction and (ii) a second rectangle having a long side which is parallel to an MD direction and shorter than the long side of the first rectangle. Note that the post 30b is made of a resin which has properties identical to those of the posts 30 in accordance with Embodiment 1.

Thus, a length of the post 30b in a contact region between the post 30b and the wiring substrate 10 (the LCP base material 11) is the longest when measured along a direction in which a linear expansion coefficient of the LCP base material 11 is high. This allows expansion of the wiring substrate 10 in the TD direction to be suppressed in a similar manner to Embodiment 1.

### Embodiment 4

The electronic component-mounted body in accordance with the present invention is not limited to the configuration illustrated in FIG. 1 of the electronic component-mounted body 1 in accordance with Embodiment 1. For example, while the electronic component-mounted body 1 illustrated in FIG. 1 has a configuration in which two posts 30 are arranged along the TD direction, it is possible to employ an alternative aspect described below.

FIG. 6 is a top view schematically illustrating a configuration of an electronic component-mounted body 4 of Embodiment 4. For easy explanation, FIG. 6 partially includes a transparent view. Further, for easy explanation, the same reference signs will be given to members having the same function as a member described in Embodiment 1, and descriptions on such a member will be omitted.

As illustrated in FIG. 6, in Embodiment 4, five posts 30c are provided in place of the two posts 30 in accordance with Embodiment 1.

Similarly to the posts 30 in accordance with Embodiment 1, each of the posts 30c is a columnar structure which stands upright between a terminal-less region of an IC chip 20 and an upper surface of a wiring substrate 10 so as to be in contact with the terminal-less region and a region of the upper surface of the wiring substrate 10 which region faces the terminal-less region. However, the posts 30c in accordance with Embodiment 4 differ from the two posts 30 in accordance with Embodiment 1 in that the posts 30b are scattered on the upper surface of the wiring substrate 10 whereas the posts 30 are arranged on the same line along the TD direction.

As with the posts 30 in accordance with Embodiment 1, the posts 30c in accordance with Embodiment 4 allow a position of the wiring substrate 10 to be fixed at a contact portion between the wiring substrate 10 and a lower end of each of the posts 30c at a heating step of a reflow process during mounting. This suppresses expansion, caused by a linear expansion coefficient of the LCP base material 11, of the wiring substrate 10 at the contact portion and a region around the contact portion. A similar effect is exhibited with respect to the IC chip 20. The posts 30c allows a position of the IC chip 20 to be fixed at a contact portion between the IC chip 20 and an upper end of each of the posts 30c at the heating step of the reflow process during the mounting. This suppresses expansion, caused by a linear expansion coefficient of the IC chip 20, of the IC chip 20 at the contact portion and a region around the contact portion.

Further, a positional arrangement of the posts 30c can be determined with a high degree of freedom in such a manner that the posts 30c can be provided at any positions in consideration of a functional surface of an integrated circuit (IC) included in the IC chip 20, and can be provided so as to avoid a portion to be left as an open space among a space below the IC chip 20.

Thus, Embodiment 4 makes it possible to achieve good flip chip mounting.

### Embodiment 5

The semiconductor device in accordance with the present invention is not limited to the configuration illustrated in FIG. 1 of the semiconductor device 1 in accordance with Embodiment 1. It is possible to employ an alternative aspect described below.

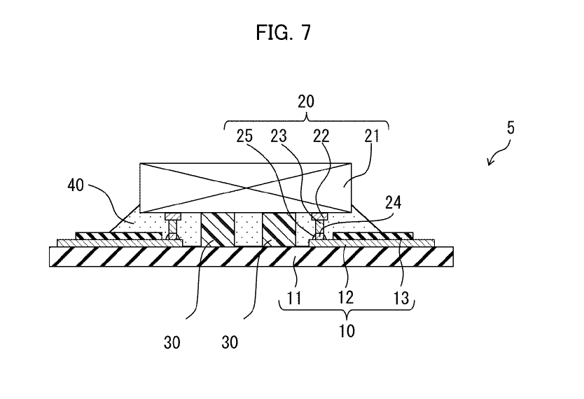

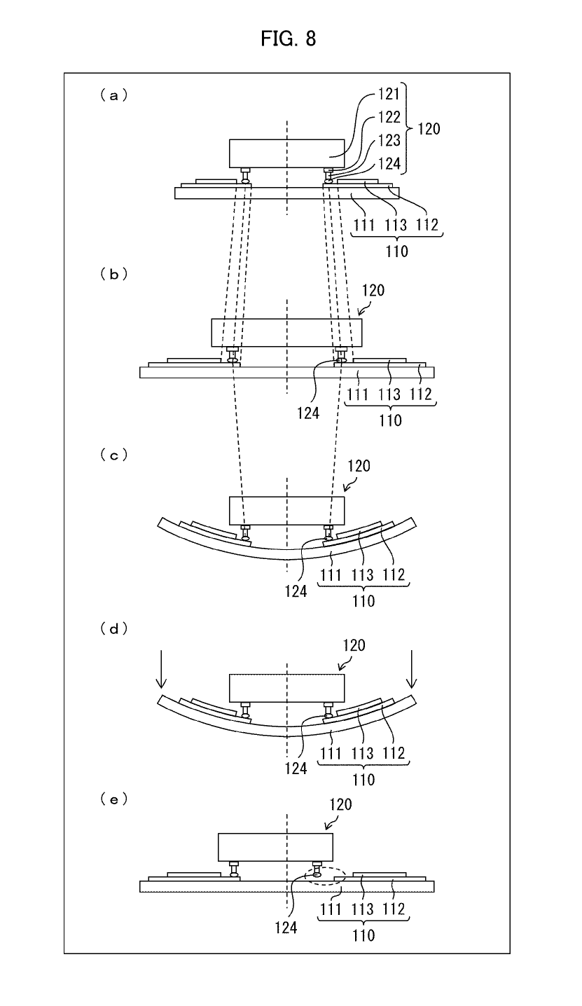

FIG. 7 is a cross-sectional view of an electronic component-mounted body 5 of Embodiment 5, the view corresponding to the electronic component-mounted body 1 illustrated in (b) of FIG. 1.

The electronic component-mounted body 5 in accordance with Embodiment 5 differs from the electronic component-mounted body 1 in accordance with Embodiment 1 in that a gap between the IC chip 20 and the wiring substrate 10 of the electronic component-mounted body 1 illustrated in (b) of FIG. 1 is filled with underfill 40 (filler).

The underfill 40 may be a conventionally well-known underfill material, but preferably is an underfill material having a low parasitic capacitance since the IC chip 20 includes an MMIC.

The underfill 40 may be provided after the posts 30 are formed. At a point in time when the posts 30 are formed, the IC chip 20 and the wiring substrate 10 are connected to each other with an improved strength as compared with a case in which the posts 30 are not provided. Accordingly, there is a reduced risk of breakage during a period after the connection by soldering is carried out until the gap is filled with the underfill material.

Thus, the provision of the underfill 40 as described above makes it possible to provide an electronic component-mounted body 5 which enables an improvement in strength of bonding between the wiring substrate and the IC chip and, accordingly, enables an improvement in reliability at a connection part between the wiring substrate and the chip.

Note that the sealing with use of the underfill material described above is also applicable to the electronic component-mounted bodies 2 through 4 of Embodiments 2 through 4.

[Recap]

An electronic component-mounted body in accordance with an embodiment of the present invention is an electronic component-mounted body including: a wiring substrate; and an electronic component including a terminal connected to wiring of the wiring substrate by soldering, the electronic component being fixed to the wiring substrate with use of a post which is made of a thermosetting resin and not in contact with the wiring and the terminal.

The configuration above allows providing an electronic component-mounted body which enables prevention of defective mounting which is caused by a difference in linear expansion coefficient between the wiring substrate and the electronic component.

That is, the electronic component and the wiring substrate are made of respective different materials, and there is a difference in linear expansion coefficient between the electronic component and the wiring substrate. However, according to the configuration above, the electronic component and the wiring substrate are fixed by a post which is cured by heat for soldering of the electronic component and the wiring substrate. This allows expansion or contraction of one of the electronic component and the wiring substrate, which one has a linear expansion coefficient greater than that of the other, to be suppressed by expansion or contraction of the other.

As such, even in a case where the wiring substrate has a linear expansion coefficient greater than that of the electronic component and expands during reflow, the curing of the post at the time of melting of the solder allows suppressing expansion of the wiring substrate, so that warpage of the wiring substrate which is caused after an end of the reflow is suppressed. Further, even in a case where the wiring substrate contracts during reflow, the curing of the post at the time of melting of the solder allows suppressing the contraction, so that warpage of the wiring substrate which is caused after an end of the reflow is suppressed. Accordingly, when an attempt is made to cancel warpage of the wiring substrate by applying an external force, less stress is exerted on a soldered portion as compared with a case in which the warpage is greater. This allows reducing a risk of breakage of the soldered portion.

Further, according to an aspect of the present invention, the electronic component-mounted body may be further configured such that: the electronic component is an IC chip including a plurality of the terminals arranged in a peripheral part of a back surface of the IC chip; and the post is provided in a region surrounded by the plurality of the terminals.

The configuration above allows providing an electronic component-mounted body which enables prevention of defective mounting which is caused by a difference in linear expansion coefficient between the wiring substrate and the IC chip.

Note that the IC chip may be an MMIC chip which will be described later.

Further, according to an aspect of the present invention, the electronic component-mounted body may be further configured such that: a linear expansion coefficient of the wiring substrate with respect to a first direction parallel to a substrate surface of the wiring substrate is greater than a linear expansion coefficient of the wiring substrate with respect to a second direction which is parallel to the substrate surface and different from the first direction; and a width of a contact surface between the wiring substrate and the post as measured along the first direction is greater than a width of the contact surface as measured along the second direction.

The configuration above allows efficiently suppressing, with use of the post having a limited volume, expansion or contraction of the wiring substrate along the first direction which expansion or contraction may be caused during reflow.

Note that the contact surface of the post, which contact surface is in contact with the wiring substrate, may have a shape of (1) an ellipse having a long axis parallel to the first direction and a short axis parallel to the second direction or (2) a cross which is a combination of (i) a first rectangle having a long side parallel to the first direction and (ii) a second rectangle having a long side which is parallel to the second direction and has a length shorter than that of the long side of the first rectangle.

Further, according to an aspect of the present invention, the electronic component-mounted body may be further configured such that: the electronic component is fixed to the wiring substrate with use of not only the post but also another post which is made of a thermosetting resin and not in contact with the wiring and the terminal; a linear expansion coefficient of the wiring substrate with respect to a first direction parallel to a substrate surface of the wiring substrate is greater than a linear expansion coefficient of the wiring substrate with respect to a second direction which is parallel to the substrate surface and different from the first direction; and the post and the other post are arranged along the first direction.

The configuration above allows efficiently suppressing, with use of a limited number of posts, expansion or contraction of the wiring substrate along the first direction which expansion or contraction may be caused during reflow.

Further, according to an aspect of the present invention, the electronic component-mounted body may be further configured such that: the wiring substrate is a liquid crystal polymer substrate including (i) a liquid crystal polymer base material and (ii) wiring provided on a surface of the liquid crystal polymer base material; and the first direction and the second direction are a TD (transverse direction) direction and a MD (machine direction) direction, respectively, of the liquid crystal polymer base material.

The configuration above allows providing an electronic component-mounted body which enables prevention of defective mounting which is caused by a difference in linear expansion coefficient between the liquid crystal polymer substrate and the electronic component.

Further, according to an aspect of the present invention, the electronic component-mounted body may be further configured such that a gap between the electronic component and the wiring substrate is filled with a resin.

The configuration above allows providing an electronic component-mounted body which enables a further improvement of reliability of connection by soldering, since the resin with which the gap is filled increases strength of bonding between the electronic component and the wiring substrate.

Further, a method, in accordance with an aspect of the present invention, for manufacturing an electronic component-mounted body is a method for manufacturing an electronic component-mounted body including a wiring substrate and an electronic component, the method including: a deposition step of causing a thermosetting resin in an uncured state to be deposited (i) on the wiring substrate into a columnar shape without bringing the thermosetting resin into contact with wiring of the wiring substrate or (ii) on the electronic component into a columnar shape without bringing the thermosetting resin into contact with a terminal of the electronic component; a contact step of bringing the terminal of the electronic component into contact with the wiring via solder without bringing the thermosetting resin into contact with the terminal and the wiring; a heating step of heating the thermosetting resin and the solder so as to cure the thermosetting resin and also to melt the solder; and a cooling step of cooling the solder so as to cure the solder.

The configuration above allows providing an electronic component-mounted body which enables prevention of defective mounting which is caused by a difference in linear expansion coefficient between the wiring substrate and the electronic component.

That is, the electronic component and the wiring substrate are made of respective different materials, and there is a difference in linear expansion coefficient between the electronic component and the wiring substrate. However, according to the configuration above, the electronic component and the wiring substrate are fixed by a post which is cured by heat for soldering of the electronic component and the wiring substrate. This allows expansion or contraction of one of the electronic component and the wiring substrate, which one has a linear expansion coefficient greater than that of the other, to be suppressed by expansion or contraction of the other.

As such, even in a case where the wiring substrate has a linear expansion coefficient greater than that of the electronic component and expands during reflow, the curing of the post at the time of melting of the solder allows suppressing expansion of the wiring substrate, so that warpage of the wiring substrate which is caused after an end of the reflow is suppressed. Further, even in a case where the wiring substrate contracts during reflow, the curing of the post at the time of melting of the solder allows suppressing the contraction, so that warpage of the wiring substrate which is caused after an end of the reflow is suppressed. Accordingly, when an attempt is made to cancel warpage of the wiring substrate by applying an external force, less stress is exerted on a soldered portion as compared with a case in which the warpage is greater. This allows reducing a risk of breakage of the soldered portion.

The present invention is not limited to the embodiments, but can be altered by a skilled person in the art within the scope of the claims. An embodiment derived from a proper combination of technical means each disclosed in a different embodiment is also encompassed in the technical scope of the present invention.

### REFERENCE SIGNS LIST

1, 2, 3, 4, 5: electronic component-mounted body
10: wiring substrate
11: liquid crystal polymer base material (LCP base material)
12: substrate wiring layer (wiring)
13: passivation layer
13a: opening
20: IC chip (electronic component)
21: semiconductor base material
22: I/O pad (terminal)
23: Cu pillar
24: solder layer
25: flux agent
30, 30a, 30b, 30c: post
31: post precursor (columnar post precursor)
40: underfill (filler)

1. An electronic component-mounted body comprising:
a wiring substrate; and
an electronic component including a terminal connected to wiring of the wiring substrate by soldering,
the electronic component being fixed to the wiring substrate with use of a post which is made of a thermosetting resin and not in contact with the wiring and the terminal.

2. The electronic component-mounted body as set forth in claim 1, wherein:
the electronic component is an IC chip including a plurality of the terminals arranged in a peripheral part of a back surface of the IC chip; and
the post is provided in a region surrounded by the plurality of the terminals.

3. The electronic component-mounted body as set forth in claim 1, wherein:
a linear expansion coefficient of the wiring substrate with respect to a first direction parallel to a substrate surface of the wiring substrate is greater than a linear expansion coefficient of the wiring substrate with respect to a second direction which is parallel to the substrate surface and different from the first direction; and
a width of a contact surface between the wiring substrate and the post as measured along the first direction is greater than a width of the contact surface as measured along the second direction.

4. The electronic component-mounted body as set forth in claim 3, wherein the contact surface between the wiring substrate and the post has a shape of an ellipse having a long axis parallel to the first direction and a short axis parallel to the second direction.

5. The electronic component-mounted body as set forth in claim 3, wherein the contact surface between the wiring substrate and the post has a shape of a cross which is a combination of (i) a first rectangle having a long side parallel to the first direction and (ii) a second rectangle having a long side which is parallel to the second direction and has a length shorter than that of the long side of the first rectangle.

6. The electronic component-mounted body as set forth in claim 1, wherein:
the electronic component is fixed to the wiring substrate with use of not only the post but also another post which is made of a thermosetting resin and not in contact with the wiring and the terminal;
a linear expansion coefficient of the wiring substrate with respect to a first direction parallel to a substrate surface of the wiring substrate is greater than a linear expansion coefficient of the wiring substrate with respect to a second direction which is parallel to the substrate surface and different from the first direction; and
the post and the other post are arranged along the first direction.

7. The electronic component-mounted body as set forth in claim 3, wherein:
the wiring substrate is a liquid crystal polymer substrate including (i) a liquid crystal polymer base material and (ii) wiring provided on a surface of the liquid crystal polymer base material; and
the first direction and the second direction are a TD (transverse direction) direction and a MD (machine direction) direction, respectively, of the liquid crystal polymer base material.

8. The electronic component-mounted body as set forth in claim 1, wherein a gap between the electronic component and the wiring substrate is filled with a resin.

9. A method for manufacturing an electronic component-mounted body including a wiring substrate and an electronic component, comprising:
a deposition step of causing a thermosetting resin in an uncured state to be deposited (i) on the wiring substrate into a columnar shape without bringing the thermosetting resin into contact with wiring of the wiring substrate or (ii) on the electronic component into a columnar shape without bringing the thermosetting resin into contact with a terminal of the electronic component;
a contact step of bringing the terminal of the electronic component into contact with the wiring via solder without bringing the thermosetting resin into contact with the terminal and the wiring;
a heating step of heating the thermosetting resin and the solder so as to cure the thermosetting resin and also to melt the solder; and
a cooling step of cooling the solder so as to cure the solder.
